(19) United States
(12) Patent Application Publication
(10) Pub. No.: US 2019/0386195 A1
(43) Pub. Date: Dec. 19, 2019

(54) LIQUID STORAGE VESSEL CONFIGURED TO GENERATE AN ELECTRICAL CURRENT

(71) Applicants: Pedram Dibaji, Redwood City, CA (US); Ashkaan Daneshi, Redwood City, CA (US); Reza Kassayan, Atherton, CA (US); Matt Aguiar, Placerville, CA (US)

(72) Inventors: Pedram Dibaji, Redwood City, CA (US); Ashkaan Daneshi, Redwood City, CA (US); Reza Kassayan, Atherton, CA (US); Matt Aguiar, Placerville, CA (US)

(21) Appl. No.: 16/008,040

(22) Filed: Jun. 14, 2018

(51) Int. Cl. H01L 35/32; H01L 35/08; G01C 9/06

(52) U.S. Cl. CPC H01L 35/32; G01C 9/06; H01L 35/08

(57) ABSTRACT

A vessel configured to generate an electrical current is disclosed. The vessel includes a reservoir configured to hold a liquid at about a first temperature, and a thermal electric module thermally coupled to the reservoir, wherein the thermal electric module is further configured to generate a first electric current. The vessel also includes a phase change material thermally coupled to the thermal electric module, the phase change material configured to absorb or release thermal energy. The vessel further includes and a temporary electrical energy storage unit electrically coupled to the thermal electric module. The vessel also includes a set of additional electric components electrically coupled to the temporary electrical energy storage unit.

### CROSS-REFERENCE TO RELATED APPLICATIONS

NONE

### FIELD OF DISCLOSURE

This disclosure relates in general to liquid storage vessels and in particular to a liquid storage vessel configured to generate an electrical current.

### BACKGROUND

Fluids are often stored in vessels configured to maintain a temperature differential between the fluid itself, and the ambient environment just outside the vessel. For example, it is desirable for hot coffee to be maintained at a temperature substantially above the ambient temperate outside the vessel, while iced coffee is generally maintained at a temperate substantially below the ambient temperate outside the vessel.

In general, a temperature differential is substantially maintained by configuring the vessel with an insulating material, or with an air gap, between an outer and inner surface of the vessel. However, since temperature equalization generally cannot be eliminated, it is generally considered a dead loss since it produces nothing of economic value or use.

Referring to FIG. 1, a simplified diagram of a spill-resistant vessel 100, commonly used for coffee and other hot beverages is shown. Vessel 100 is further comprised of reservoir 110 for containing a liquid 114, and cap 102, commonly configured to securely attach to base 103, via threading or a friction fit 108. Other than removal of cap 102, liquid 114 may also be extracted, at a reduced flow, through channel 107, by depressing surface 106.

In view of the foregoing, it would be beneficial to take advantage of the temperature gradient between the fluid inside the vessel and the ambient environment outside the vessel, in order to generate electrical current, that may in turn, power an electrical circuit.

### SUMMARY

The invention relates, in one embodiment, to a vessel configured to generate an electrical current is disclosed. The vessel includes a reservoir configured to hold a liquid at about a first temperature, and a thermal electric module thermally coupled to the reservoir, wherein the thermal electric module is further configured to generate a first electric current. The vessel also includes a phase change material thermally coupled to the thermal electric module, the phase change material configured to absorb or release thermal energy. The vessel further includes and a temporary electrical energy storage unit electrically coupled to the thermal electric module. The vessel also includes a set of additional electric components electrically coupled to the temporary electrical energy storage unit.

### BRIEF DESCRIPTION OF THE DRAWINGS

The present invention is illustrated by way of example, and not by way of limitation, in the figures of the accompanying drawings, and in which like reference numerals refer to similar elements, and in which:

FIG. 1 shows a schematic illustration of a spill-resistant vessel;

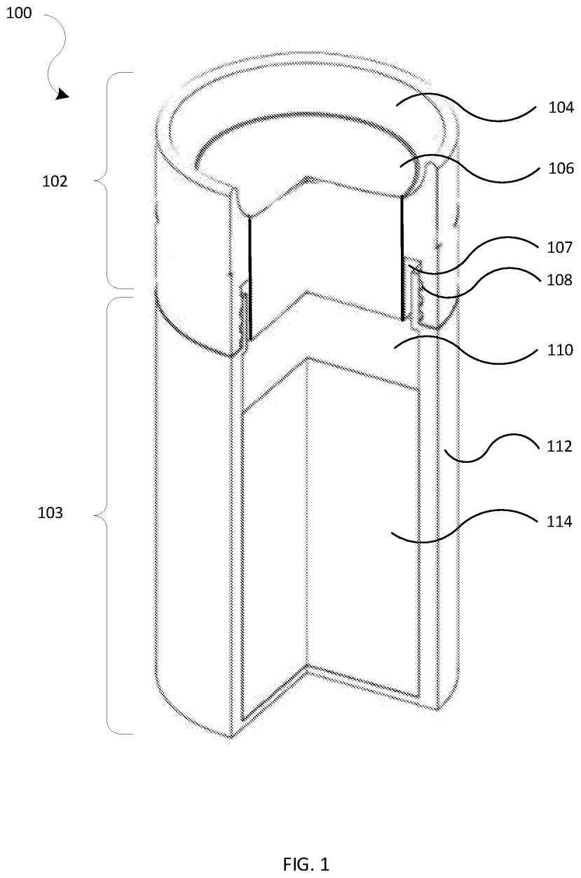

FIG. 2 shows a simplified diagram of a thermoelectric module, in accordance with the invention;

FIG. 3 shows a simplified diagram of a spill-resistant vessel, in accordance with the invention;

FIG. 4 shows a simplified schematic of electrical circuit, in accordance with the invention; and,

FIG. 5 shows a simplified schematic of the additional electrical components as set forth in FIG.4, in accordance with the invention.

### DETAILED DESCRIPTION

The present invention will now be described in detail with reference to a few preferred embodiments thereof as illustrated in the accompanying drawings. In the following description, numerous specific details are set forth in order to provide a thorough understanding of the present invention. It will be apparent, however, to one skilled in the art, that the present invention may be practiced without some or all of these specific details. In other instances, well known process steps and/or structures have not been described in detail in order to not unnecessarily obscure the present invention.

In general, the temperature of a fluid inside a vessel will tend to equalize with that of the ambient environment just outside the vessel, with the rate of equalization related to the thermal conductivity of the vessel walls. In general, this equalization is a dead loss since it does not tend to produce anything of value or use.

An electrical circuit including a TEM or thermoelectric module (also known as a thermoelectric generator) may be added to the vessel, further coupled to an energy storage medium, in order to power an electrical device, such as a light emitting diode.

However, since the amount of current generated by the TEM is relatively small, it is difficult to design a circuit configuration optimized for a very low current configuration

In an advantageous manner, an Enhanced Boost Converter may be integrated into the electrical circuit, such that the current draw of the overall circuit is minimized when engaged.

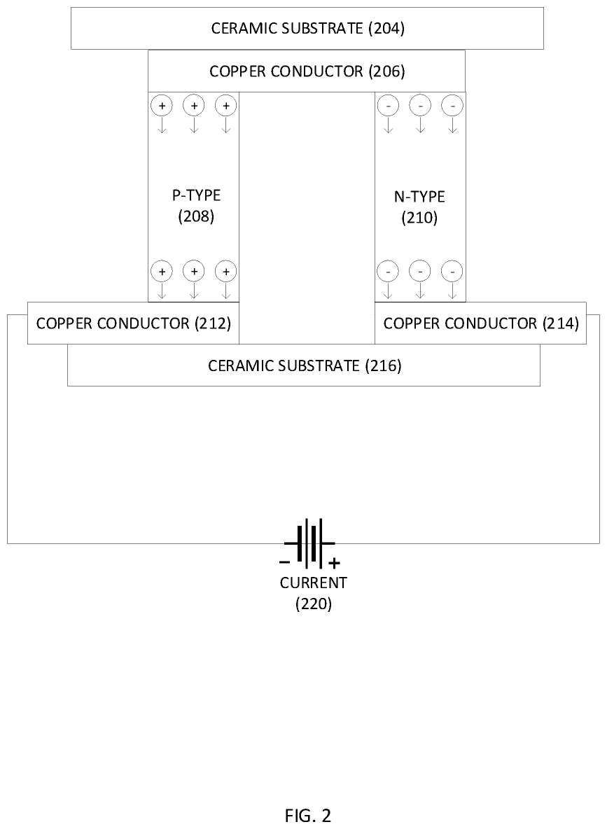

Referring to FIG. 2, a simplified diagram of a thermoelectric module is shown, in accordance with the invention. In general, a thermoelectric module is a solid-state heat pump that takes advantage of the fact that electrons are both carriers of electricity and heat. If a temperature gradient exists between two dissimilar semiconductors, an electric current is generated between those semiconductors.

Here, in accordance with the invention, a thermoelectric module is selected, consisting of an array of p-type 208 and n-type 210 semiconductor elements that are heavily doped with electrical carriers. In general, these elements are electrically connected in series via a set of copper conductors 206, 212, & 214, but thermally connected in parallel via a set of ceramic substrates 204 & 216, one on each side of the elements. Consequently, a Temperature differential between ceramic substrate 204 and ceramic substrate 216 causes a current to be created. In addition, the Temperature differential between 204 & 216 can be positive or negative.

In addition, in order to substantially maintain a temperature difference ceramic substrate 204 and ceramic substrate 216, a phase change material or PCM may be coupled to one surface of the TEM. In general, a PCM is a substance with a high heat of fusion which, melting and solidifying at a certain Temperature, is capable of storing and releasing large amounts of energy. Consequently, when a temperature differential between a fluid within a vessel, and the ambient temperature outside the vessel, is minimal, a greater temperature differential may still exist between ceramic substrate 204 and ceramic substrate 216, allowing a current to be generated.

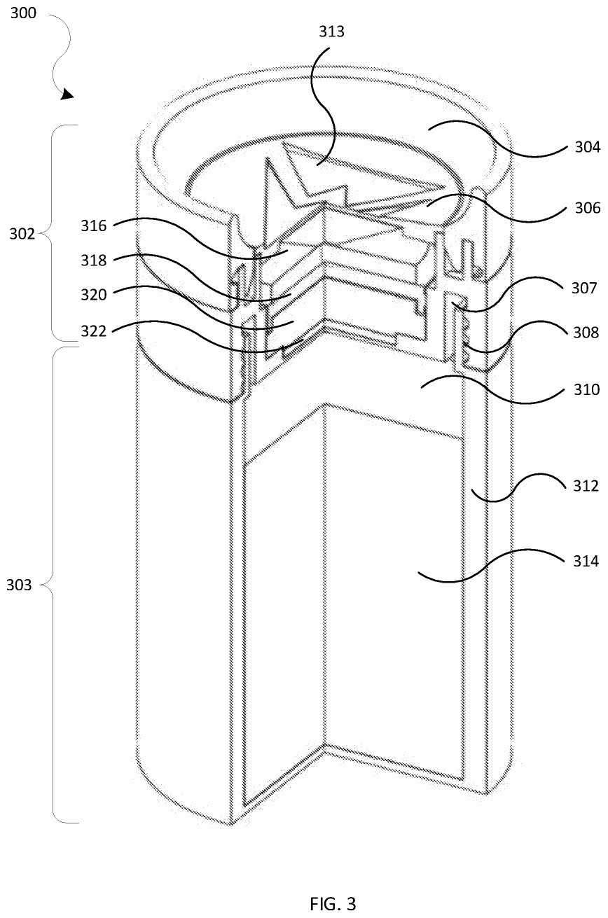

Referring to FIG. 3, a simplified diagram of a spill-resistant vessel is shown, in accordance with the invention. In general, vessel 300 is comprised of reservoir 310 for containing fluid 314, and cap 302, commonly configured to securely attach to reservoir 310, via threading or a friction fit 308. Other than removal of cap 302, liquid 314 may also be extracted at a reduced flow, through channel 307, by depressing surface 306.

In an advantageous manner, TEM 322 is configured to be in thermal contact with both fluid 314 and PCM 320, generating an electrical current where there is a sufficient temperature differential between the two. In addition, the current may be directed to a circuit 318 to power any coupled electronic components, such as a set of diodes configured to illuminate a translucent cutout 313 of surface 306.

In one configuration, the illumination is facilitated with a light pipe configured with a set of LEDs (light-emitting diode). In general, a light pipe is an optical fiber or a solid transparent plastic rod for transmitting light from an LED to a user interface, here translucent cutout 313.

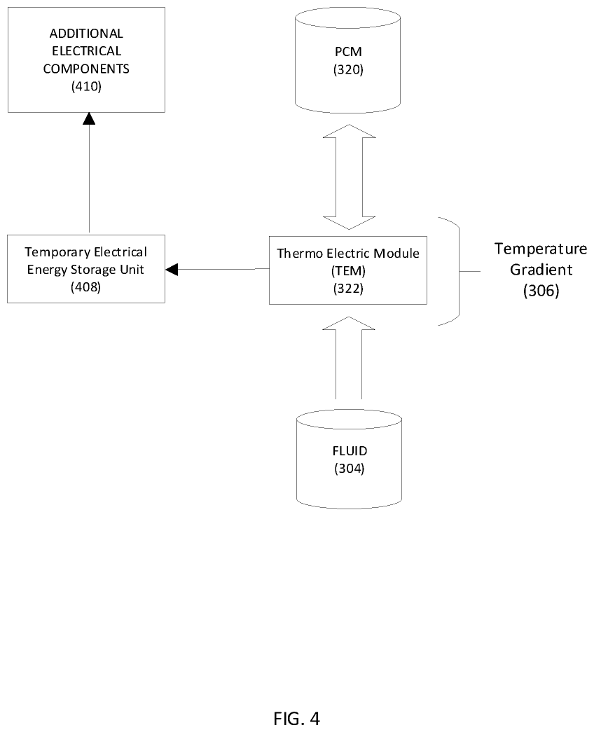

Referring to FIG. 4, a simplified schematic of electrical circuit 318 is shown in accordance with the invention. In general, TEM 322 is thermally coupled to both fluid 304 (if present) and PCM 320. Temperature gradient 306 between fluid 304 and PCM 320 allows a current to be generated and subsequently stored in temporary electrical energy storage unit 408. The invention is configured to use temporary electrical energy storage to facilitate initial kick-start for better user experience and immediate turn-on. In one embodiment, the temporary electrical energy storage unit comprises a super capacitor. In another embodiment, the temporary electrical energy storage unit 408 comprises a rechargeable battery. Temporary electrical energy storage unit 408, in turn, may be electrically coupled to additional electrical components 420.

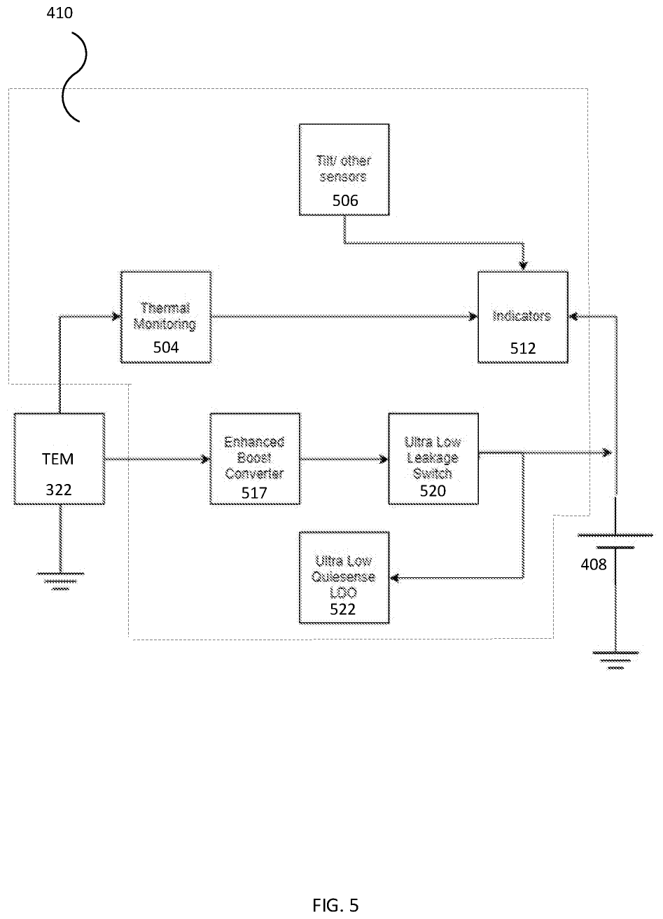

Referring to FIG. 5, a more detailed schematic of the additional electrical components 420 (as set forth in FIG. 4) is shown, in accordance with the invention. In general, a thermal monitoring circuit 504 and an enhanced boost converter 517 may be electrically coupled to TEM 322.

In an advantageous manner, thermal monitoring circuit 504 may include a thermistor, which is generally an electrical resistor whose resistance is directly affected by temperature. In a positive temperature coefficient (PTC) thermistor, resistance generally increases with increasing temperature. In a negative temperature coefficient (NTC) thermistor, resistance generally decreases with increasing temperature. Thermistors generally comprise a set of metallic oxides, pressed into a bead, disk, or cylindrical shape and then encapsulated with an impermeable material such as epoxy or glass.

The current invention is configured with a NTC thermistor, thermally coupled the outer surface of reservoir 310 (not shown), such that the temperature of the thermistor is substantially the same as that of a fluid inside reservoir 310.

The thermistor may then be powered by a small substantially constant current (thermistor current) whose voltage (thermistor voltage) is compared to a substantially fixed reference voltage using a low power comparator. In one embodiment, the thermistor current is preferably less than 700 nA. In another embodiment, the thermistor current is more preferably less than about 60 nA. In another embodiment, the thermistor current is less than about 5 nA.

When the thermistor voltage is substantially equal to the fixed reference voltage, a signal is transmitted to indicators circuit 512, which, in turn, may present to a user, visually indicia of the fluid temperature, such as a color or a set of colors. In one configuration, the visual indicia are presented through a light pipe.

In an alternate embodiment, the acoustic indicia are presented to a user.

In addition, in an advantageous manner, enhanced boost converter 517 may be used to step up the voltage (while stepping down current) from an input (supply) to an output (load). In general, an enhanced boost converter t is a class of switched-mode power supply (SMPS) containing at least two semiconductors (a diode and a transistor) and at least one energy storage element: a capacitor, inductor, or the two in combination.

In the current invention, as the voltage generated by TEM is generally very low, a boost converter may be used to charge the rechargeable battery 408 to a higher voltage and to use the stored energy at a later time. Operation of a boost converter requires turning on/off a switch. In our case a MOSFET switch is used for switching. Gate of a MOSFET acts like a capacitor and turning it ON and OFF requires charging and discharging the gate rapidly. To minimize the charge needed to operate this DC/DC converter, the control circuitry that operates the switch looks into the available charge at the input and toggles the switch according to the input voltage in a linear fashion. This input voltage in this case is the TEM voltage. As the TEM voltage drops, the control circuitry reduces the speed of the operation. When the input reaches zero, the switch stops working completely to minimize any charge waste.

The invention has been described with reference to various specific and illustrative embodiments. However, it should be understood that many variations and modifications may be made while remaining within the spirit and scope of the invention.

Having disclosed exemplary embodiments and the best mode, modifications and variations may be made to the disclosed embodiments while remaining within the subject and spirit of the invention as defined by the following claims.

What is claimed is:

1. A vessel configured to generate an electrical current comprising:
a reservoir configured to hold a liquid at about a first temperature;
a thermal electric module thermally coupled to the reservoir, wherein the thermal electric module is further configured to generate a first electric current;
a phase change material thermally coupled to the thermal electric module, the phase change material configured to absorb or release thermal energy;
a temporary electrical energy storage unit electrically coupled to the thermal electric module; and
a set of additional electric components electrically coupled to the temporary electrical energy storage unit.

2. The vessel of claim 1, wherein the set of additional electric components further includes a thermal monitoring circuit.

3. The vessel of claim 2, wherein the thermal monitoring circuit further includes a thermistor.

4. The vessel of claim 3, wherein the thermistor is thermally coupled to the reservoir.

5. The vessel of claim 3, wherein the thermistor is coupled to a thermistor voltage source and a reference voltage source, wherein if a thermistor voltage exceeds a reference voltage, a signal is sent to an indicators circuit.

6. The vessel of claim 5, wherein the thermistor voltage is compared to the reference voltage using a low power comparator.

7. The vessel of claim 6, wherein the thermistor includes a second current.

8. The vessel of claim 7, wherein the second current is preferably less than 700 nA.

9. The vessel of claim 7, wherein the second current is more preferably less than about 60 nA.

10. The vessel of claim 7, wherein the second current is most preferably less than about 5 nA.

11. The vessel of claim 1, wherein the thermal electric module is coupled to an enhanced boost converter.

12. The vessel of claim 1, wherein the set of additional electric components further includes an enhanced boost converter.

13. The vessel of claim 5, wherein the set of additional electric components further includes an indicators circuit.

14. The vessel of claim 13, wherein the indicators circuit is electrically coupled to a set of light emitting diodes.

15. The vessel of claim 14, wherein the set of light emitting diodes display a different color corresponding to a temperature measured by the thermal monitoring circuit.

17. The vessel of claim 1, wherein the set of additional electric components further includes a set of tilt sensors.

18. The vessel of claim 17, wherein the set of tilt sensors is electrically coupled to the indicators circuit.

19. The vessel of claim 1, wherein temporary electrical energy storage unit comprises a super capacitor.

20. The vessel of claim 1, wherein temporary electrical energy storage unit comprises a rechargeable battery.
